(19) United States
(12) Patent Application Publication
(10) Pub. No.: US 2025/0212579 A1
(43) Pub. Date: Jun. 26, 2025

(54) METHOD OF MANUFACTURING AN ELECTRONIC DEVICE

(71) Applicant: Aledia, Champagnier (FR)

(72) Inventors: Frédéric Mayer, Moirans (FR); Alexander Bietsch, Montbonnot Saint Martin (FR); Thibault Catelain, Grenoble (FR); Gabriel Louro de Oliveira, Brie et Angonnes (FR)

(73) Assignee: Aledia, Champagnier (FR)

(21) Appl. No.: 18/985,454

(22) Filed: Dec. 18, 2024

(30) Foreign Application Priority Data
Dec. 22, 2023 (FR) 2315024

(51) Int. Cl. H10H 29/03; H10H 29/24

(52) U.S. Cl. CPC H10H 29/03; H10H 29/24

(57) ABSTRACT

A method of manufacturing an electronic device, including the forming, in a first handle having first and second opposite surfaces, of grooves in the first surface, the bonding of the first handle to a second handle on the side of the first surface, the thinning of the first handle on the side of the second surface, the manufacturing of a plate including a plurality of copies of the electronic device, the bonding of the plate to the second surface of the first handle, the forming of trenches in the plate in line with the grooves, the removal of the second handle, and the breakage of the first handle at the bottom of the grooves to separate the electronic devices.

### CROSS REFERENCE TO RELATED APPLICATION

The present patent application claims priority of French patent application FR23/15024 which is incorporated herein by reference.

### TECHNICAL FIELD

The present disclosure generally concerns methods of manufacturing electronic devices, in particular optoelectronic devices comprising light-emitting diodes.

### PRIOR ART

An example of a method of manufacturing an electronic device comprises the forming, on a support, of a plate comprising a plurality of copies of the electronic device, followed by the separation of the electronic devices. The separation of the electronic devices can be achieved by cutting of the plate and of the support, in particular by sawing. Such a cutting process may be difficult to implement when the electronic devices each occupy a small surface area.

A method of separation of electronic devices enabling to obtain cutting lines of small width comprises the local embrittlement of the support by a laser treatment enabling to break the support by mechanical action to separate the electronic devices. A disadvantage is that a laser treatment may damage the electronic device components close to cutting lines. This disadvantage may be particularly marked when the electronic devices each comprise a plurality of three-dimensional semiconductor elements of nanometer- or micrometer-range dimensions, separated by an electrically-insulating material. Indeed, the dimensions of the three-dimensional semiconductor elements and the distance separating the three-dimensional semiconductor elements being small, the thermal dissipation of the heat generated by the laser treatment may result in damage to the three-dimensional semiconductor elements close to cutting lines.

### SUMMARY OF THE INVENTION

An embodiment overcomes all or part of the disadvantages of known methods of manufacturing electronic devices.

An object of an embodiment is for the components of electronic devices close to cutting lines not to be damaged.

An embodiment provides a method of manufacturing an electronic device comprising the following steps:
forming, in a first handle having opposite first and second surfaces, of grooves in the first surface;
bonding of the first handle to a second handle on the same side of the first surface;
thinning of the first handle on the side of the second surface;
manufacturing of a plate comprising a plurality of copies of the electronic device;
bonding of the plate to the second surface of the first handle;
forming of trenches in the plate in line with the grooves;
removal of the second handle; and
breakage of the first handle at the bottom of the grooves to separate the electronic devices.

Advantageously, the first handle is thinned to facilitate the breaking thereof. Further, advantageously, the steps of forming of the grooves and of thinning of the first handle do not damage the electronic devices of the plate, since these steps are carried out before bonding of the plate to the first handle. Further, the bonding of the plate to the second surface of the first obtained handle being performed after the thinning of the first handle, a surface condition of the second surface at the end of the thinning step adapted for the step of bonding of the plate to the first handle can then be more easily obtained. A better control of the quality of the bonding of the plate to the first handle can advantageously be obtained. Further, the forming of the trenches in the plate in line with the grooves, and the breaking of the first handle at the location of the trenches, facilitates the separation of the electronic devices with no deterioration of the electronic components of the electronic devices.

According to an embodiment, the grooves are formed by laser etching. Advantageously, the laser treatment does not damage the electronic components of the electronic devices, since it is carried out before the bonding of the plate to the first handle.

According to an embodiment, the bonding of the first handle to the second handle is performed by bonding with a first layer of adhesive. The first adhesive layer advantageously enables to achieve a temporary bonding between the first handle and the second handle. This means that the first handle is bonded to the second handle by the adhesive layer and can then be easily detached from the second handle. Advantageously, the first adhesive layer is located on the side of the first surface of the first handle, while the step of thinning of the first handle is carried out on the side of the second surface of the first handle. The first adhesive layer does not interfere with the implementation of the thinning step. In particular, the first adhesive layer does not interfere with the operation of a grinding or polishing tool used during the thinning step and is compatible with thinning techniques so as to maintain the bonding. At the end of the thinning step, a surface condition of the second surface adapted for the step of bonding, for example by gluing, of the plate to the first handle, can then be more easily obtained. A better control of the quality of the bonding, for example by gluing, of the plate to the first handle can advantageously be obtained.

According to an embodiment, the step of removal of the second handle further comprises a step of removal, total or partial, of the first adhesive layer.

According to an embodiment, the bonding of the plate to the first handle is performed by gluing with a second layer of adhesive. According to the envisaged applications, the bonding between the plate and the first handle is a permanent bonding. The properties of the second adhesive layer may thus be different from the properties of the first adhesive layer.

According to an embodiment, the trenches further extend in the second adhesive layer.

According to an embodiment, the bonding of the plate to the first handle is performed by molecular bonding. This advantageously enables to avoids the presence of the second adhesive layer.

According to an embodiment, the trenches are formed by etching of the plate by dry etching or wet etching.

According to an embodiment, the step of bonding of the plate to the first handle comprises a step of positioning of first marks of the first handle relative to second marks of the plate, so that each electronic device to be separated is positioned between four grooves from among the grooves.

According to an embodiment, the first handle is at least partly made of glass, of quartz, or of sapphire.

According to an embodiment, when projected in a plane parallel to the second surface, one of the grooves is located between each pair of adjacent electronic devices.

An embodiment also provides a structure comprising:
a first handle having first and second surfaces and grooves in the first surface;
a plate comprising a plurality of copies of an electronic device bonded to the first handle on the side of the second surface; and
a second handle bonded to the first handle on the side of the first surface.

According to an embodiment, the structure further comprises a first layer of adhesive between the first handle and the second handle.

According to an embodiment, the structure further comprises a second layer of adhesive between the plate and the first handle.

According to an embodiment, when projected in a plane parallel to the second surface, one of the grooves is located between each pair of adjacent electronic devices.

According to an embodiment, the grooves delimit pads in the first handle, each pad facing a single one of the electronic device.

An embodiment also provides an electronic system comprising an electronic device having a first side wall and a block having opposite first and second surfaces and a second side wall, the electronic device being bonded to the second surface, the electronic system further comprising flanks containing the first side wall, the second side wall and a portion coupling the first side wall to the second side wall projecting from the first side wall and from the second side wall.

According to an embodiment, the electronic device comprises light-emitting diodes. The forming of the grooves advantageously does not result in a deterioration of the light-emitting diodes next to the desired cutting lines.

According to an embodiment, each light-emitting diode comprises a three-dimensional semiconductor element of nanometer- or micrometer-range dimensions, corresponding to a microwire, a nanowire, or a pyramid-shaped structure of nanometer- or micrometer-range dimensions, and an active layer covering the three-dimensional semiconductor element.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1A, FIG. 1B, FIG. 2A, FIG. 2B, FIG. 3, FIG. 4, FIG. 5, FIG. 6, FIG. 7, FIG. 8, FIG. 9, and FIG. 10 are cross-section views, partial and simplified, of the structure obtained at steps of an embodiment of a method of manufacturing an electronic device, FIG. 1B being similar to FIG. 1A and illustrating a variant, and FIG. 2B being similar to FIG. 2A and illustrating a variant;

FIG. 11 is cross-section view, partial and simplified, of an electronic system comprising the electronic device obtained according to the manufacturing method illustrated in FIGS. 1 to 10;

FIG. 12, FIG. 13, and FIG. 14 are cross-section views, partial and simplified, of structures obtained at steps of another embodiment of a method of manufacturing an electronic device;

FIG. 15 is a cross-section view, partial and simplified, of the structure obtained at a step of another embodiment of a method of manufacturing an electronic device;

FIG. 16 is a cross-section view, partial and simplified, of the structure obtained at a step of another embodiment of a method of manufacturing an electronic device;

FIG. 17 is a cross-section view, partial and simplified, of an embodiment of a support;

FIG. 18, FIG. 19, FIG. 20, FIG. 21, FIG. 22, FIG. 23, FIG. 24, FIG. 25, FIG. 26, FIG. 27, FIG. 28, FIG. 29, and FIG. 30 are cross-section views, partial and simplified, of structures obtained at steps of an embodiment of a method of manufacturing an optoelectronic device comprising light-emitting diodes; and

FIG. 31, FIG. 32, and FIG. 33 are cross-section views, partial and simplified, of embodiments of light-emitting diodes.

### DESCRIPTION OF EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%. In the case of an angle, the expressions “about”, “approximately”, “substantially”, and “in the order of” signify to within 10°, preferably to within 5°. Further, it is here considered that the terms “insulating” and “conductive” respectively signify “electrically insulating” and “electrically conductive”.

By optoelectronic devices, there is meant devices adapted to performing the conversion of an electrical signal into electromagnetic radiation or conversely, and in particular devices dedicated to the detection, the measurement, or the emission of electromagnetic radiation.

The transmittance of a layer corresponds to the ratio of the intensity of the radiation coming out of the layer through an exit surface to the intensity of the radiation entering the layer through an entrance surface opposite to the exit surface. In the rest of the description, a layer or a film is said to be opaque to a radiation when the transmittance of the radiation through the layer or the film is lower than 10%. For the rest of the disclosure, a layer or a film is said to be transparent to a radiation when the transmittance of the radiation through the layer or the film is higher than 10%.

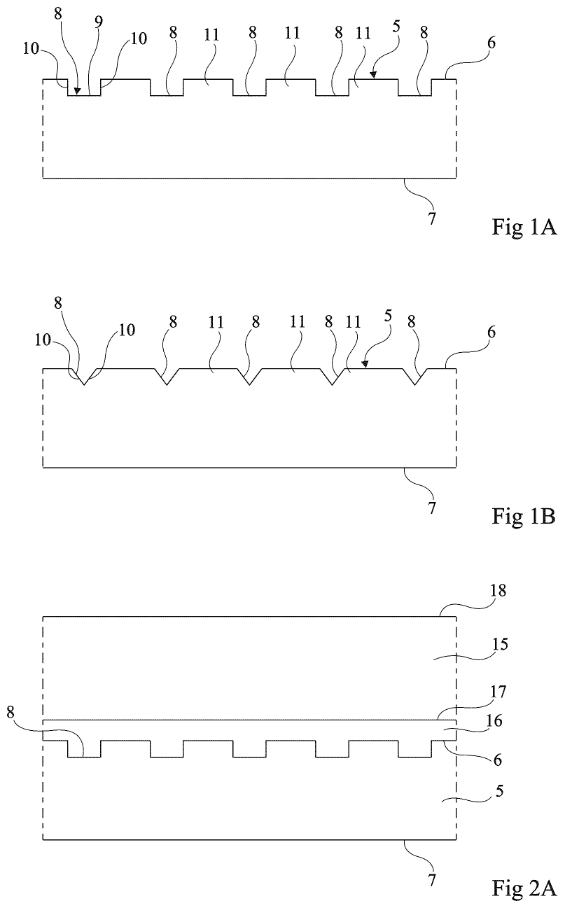

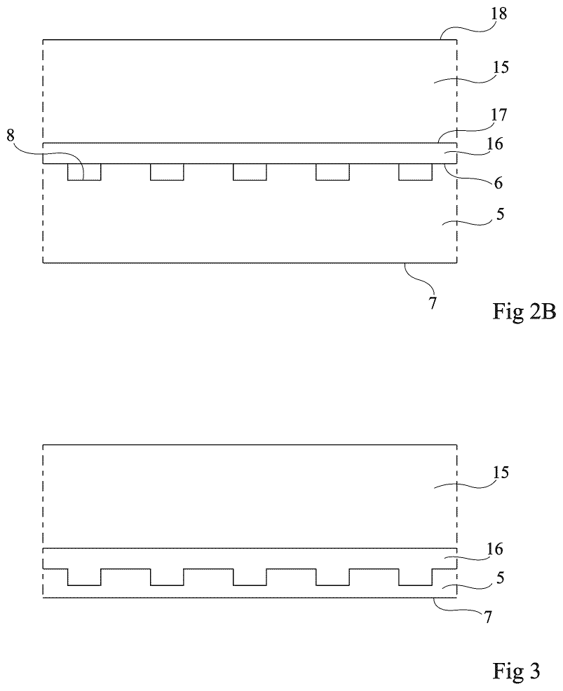

FIG. 1A, FIG. 2A, FIG. 3, FIG. 4, FIG. 5, FIG. 6, FIG. 7, FIG. 8, FIG. 9, and FIG. 10 are cross-section views, partial and simplified, of the structure obtained at steps of an embodiment of a method of manufacturing an electronic device.

FIG. 1A is a cross-section view, partial and simplified, of the structure obtained after a step of forming in a first handle 5, comprising two opposite surfaces 6, 7, of grooves 8 extending from surface 6, eight grooves 8 being shown as an example in FIG. 1A.

According to an embodiment, surfaces 6 and 7 are parallel. According to an embodiment, surfaces 6 and 7 are planar. According to an embodiment, the thickness of first handle 5, outside grooves 8, is in the range from 50 μm and 3 mm. According to an embodiment, first handle 5 has a monolayer or multilayer structure. According to an embodiment, first handle 5 is transparent to visible light. According to an embodiment, first handle 5 is made of glass, of quartz, or of sapphire. According to an embodiment, grooves 8 are rectilinear.

Each groove 8 is characterized by a depth and a width. It typically comprises a bottom 9 and side walls 10. According to the cross-section of groove 8, bottom 9 may be rounded or even disappear if side walls 10 are “V”-shaped. According to an embodiment, each groove 8 extends in first handle 5, from the surface 6 of first handle 5, down to a depth in the range from 5 μm to 200 μm, for example equal to approximately 30 μm. According to an embodiment, each groove 8 has a width in the range from 1 μm to 100 μm.

FIG. 1B is a drawing similar to FIG. 1A and illustrates grooves 8, each having a “V”-shaped cross-section with inclined side walls 10.

Grooves 8 delimit pads 11 in first handle 5 separated from one another.

According to an embodiment, grooves 8 are formed by laser etching, by chemical etching (wet or dry), by mechanical sawing, or by a combination of these techniques. According to an embodiment, the wavelength of the laser beam used to etch grooves 8 is in the range from 100 nm to 3,000 nm, according to the material to be etched. According to an embodiment, the laser beam is emitted in the form of a pulse, of two pulses, or of more than two pulses, each pulse having a duration in the range from 0.1 ps to 1,000 ps. The energy of the laser beam for each pulse is in the range from 1 μJ to 100 μJ.

FIG. 2A is a cross-section view, partial and simplified, of the structure obtained after the bonding of a second handle 15 to first handle 5 by means of a layer of adhesive 16, which enables to temporarily bond the second handle to the first handle. This signifies that first handle 5 is bonded to second handle 15 by adhesive layer 16 and can then be easily detached from second handle 15. Second handle 15 is bonded to first handle 5 on the side of surface 6, that is, on the side of grooves 8. According to an embodiment, the adhesive penetrates into grooves 8. Second handle 15 comprises two opposite surfaces 17, 18, adhesive layer 16 being in direct physical contact with surface 17. According to an embodiment, surfaces 17 and 18 are parallel. According to an embodiment, surfaces 17 and 18 are planar. According to an embodiment, the thickness of second handle 15 is in the range from 50 μm to 3 mm. According to an embodiment, second handle 15 is made of silicon or other semiconductor material, of glass, of quartz, or of sapphire.

FIG. 2B is a drawing similar to FIG. 2A and illustrates a variant according to which adhesive layer 16 does not penetrate into grooves 8.

The thickness of adhesive layer 16 is in the range from 10 μm to 300 μm. According to an embodiment, adhesive layer 16 is made of an organic or inorganic matrix material having adhesion properties and disbonding properties. This material may be a composite, a single layer, or a multilayer material.

FIG. 3 is a cross-section view, partial and simplified, of the structure obtained after a step of thinning of first handle 5 from surface 7. According to the nature of the material or of the materials forming first handle 5, the thinning step may be performed by grinding and/or by CMP (Chemical-Mechanical Polishing). The CMP step may comprise, simultaneously or successively, mechanical polishing steps and chemical etching steps. At the end of the thinning step, the thickness of first handle 5 is in the range from 30 μm to 200 μm.

At the end of the thinning step, the thickness of first handle 5 at the bottom of each groove 8 is sufficiently low to allow the implementation of a step of breakage of first handle 5 at the bottom of each groove 8 in a subsequent step of the method described hereafter, and is sufficiently high to prevent an incidental breakage of first handle 5 at the bottom of one of grooves 8 before the breakage step is carried out, even though first handle 5 may be subjected to a bending during the steps of the method.

Advantageously, adhesive layer 16 is located on the side of surface 6 of first handle 5, while the thinning step is carried out on side of surface 7 of first handle 5. Adhesive layer 16 does not interfere with the implementation of the thinning step. In particular, adhesive layer 16 does not interfere with the operation of a grinding or polishing tool used during the thinning step.

FIG. 4 is a cross-section view, partial and simplified, of the structure obtained after the manufacturing of a plate 20 on a substrate 21, plate 20 comprising a plurality of copies of an electronic device 22, four copies of electronic device 22 being entirely shown as an example in FIG. 4. Plate 20 comprises an upper surface 23 and a lower surface 24, opposite to upper surface 23. Lower surface 24 is in contact with substrate 21. Upper surface 23 is preferably planar. According to an embodiment, the thickness of plate 20 is in the range from 1 μm and 100 μm, preferably from 10 μm to 20 μm. Electronic device 22 comprises at least one electronic component 25, a single electronic component 25 being very schematically shown as an example for each electronic device 22 of FIG. 4. According to an embodiment, electronic device 22 is an optoelectronic device. Electronic components 25 can then comprise light sources, in particular light-emitting diodes.

FIG. 5 is a cross-section view, partial and simplified, of the structure obtained after the bonding of plate 20 to first handle 5. More precisely, the upper surface 23 of plate 20 is bonded to the surface 7 of first handle 5, that is, on the side opposite to grooves 8. According to an embodiment, plate 20 is bonded to first handle 5 via an adhesive layer 30. Adhesive layer 30 is made of an organic or inorganic matrix material having adhesion properties and optical properties enabling to transmit light in the visible spectrum, and is for example made of an epoxy-based material, in particular a SU-8 type resist, a resin based on benzocyclobutene (BCB), an optical adhesive marketed under name NOA or also under name IBA. This material may be a composite, a single layer, or a multilayer material. The thickness of adhesive layer 30 is in the range from 1 μm to 40 μm. According to an embodiment, adhesive layer 30 corresponds to an optical adhesive. In particular, when electronic device 22 comprises a light-emitting diode, adhesive layer 30 may be transparent to the radiation of the light-emitting diode. As described hereabove, glue layer 16 does not interfere with the step of thinning of first handle 5, so that at the end of the thinning step, it is easier to obtain a surface condition of surface 7 adapted for the step of bonding, for example by gluing, of plate 20 to first handle 5. A better control of the quality of the bonding, for example by gluing, of plate 20 to first handle 5 can advantageously be obtained.

Grooves 8 are located in line with desired cutting lines between electronic devices 22. The cutting lines are schematically indicated by dashed lines 29 in FIG. 5. The desired cutting lines 29 between electronic devices 22 and grooves 8 are superimposed in a direction orthogonal to surface 7, the desired cutting lines 29 overlapping grooves 8 in a direction orthogonal to surface 7. In other words, cutting lines 29 face the pattern formed by grooves 8 in a direction orthogonal to surface 7. Cutting lines 29 correspond to the portions of plate 20 to be removed to obtain the separation of electronic devices 22. The correct positioning of plate 20 relative to first handle 5 is obtained by using, for example, marks on plate 20 and marks on first handle 5 (the marks not being shown). According to an embodiment, when projected in a plane parallel to surface 7, the electronic component 25 or the electronic components 25 of each electronic device 22 are surrounded by grooves 8. This means, when projected in a plane parallel to surface 7, that a groove 8 is located between the electronic component 25 or the electronic components 25 of each electronic device 22 of two adjacent electronic devices 22. Each pad 11 thus faces a single one of the electronic devices 22.

FIG. 6 is a cross-section view, partial and simplified, of the structure obtained after the removal of substrate 21 to expose the lower surface 24 of plate 20 and after a step of forming, on the surface 24 of plate 20, of electrical connection elements of electronic devices 22, for example solder balls 31 or connection pads. The step of removal of substrate 21 is carried out, for example, by grinding, by dry etching, particularly plasma etching, or by wet etching, or by chemical-mechanical polishing, also called CMP.

FIG. 7 is a cross-section view, partial and simplified, of the structure obtained after the forming of trenches 32 in plate 20, and possibly in adhesive layer 30, to delimit the electronic devices 22 to be separated. Trenches 32 are formed on the cutting lines 29 desired between electronic devices 22. Each trench 32 comprises a bottom 33 and side walls 34. Trenches 32 may extend in adhesive layer 30 so as to reach the surface 7 of first handle 5. According to an embodiment, trenches 32 do not extend in first handle 5. According to another embodiment, the bottom 33 of trench 32 corresponds to a portion of the surface 7 of first handle 5. According to an embodiment, the depth of each trench 32 is in the range from 10 μm to 80 μm. According to an embodiment, the width of each trench 32 is in the range from 1 μm and 50 μm, preferably from 30 μm to 40 μm. Trenches 32 are formed in line with grooves 8. This means that each trench 32 is aligned with one of grooves 8. According to an embodiment, trenches 32 are formed by etching, for example, by dry etching, in particular plasma etching, or by mechanical sawing.

FIG. 8 is a cross-section view, partial and simplified, of the structure obtained after the bonding of the structure obtained in FIG. 7 to an adhesive film 35, for example made of stretchable material, arranged on the side of solder balls 31. According to an embodiment, adhesive film 35 is made of a material comprised in the group comprising the materials described in patents U.S. Pat. Nos. 4,222,913 and 4,379,197, polyethylene resins with no polymerized vinyl acetate group, acrylate polymers such as the following components: 2-ethylhexyl acrylate, n-butyl acrylate, methyl acrylate, and t-butyl methacrylate. A stretchable material is defined as being a material having a modulus of longitudinal elasticity, that is, the ratio of the stress to the relative elongation, in the range from 102 Pa to 106 Pa. Preferably, film 35 is adapted to deforming with an elongation at break greater than 150%, preferably greater than 300%.

FIG. 9 is a cross-section view, partial and simplified, of the structure obtained after the removal of second handle 15 and the removal of adhesive layer 16 to expose the surface 6 and the grooves 8 of first handle 5. As a variant, adhesive layer 16 may not be completely removed, but only partially. First handle 5, which forms a continuous shield, advantageously plays a role of protection of electronic devices 22 on removal of second handle 15 and on removal, total or partial, of adhesive layer 16.

According to an embodiment, the material forming adhesive layer 16 enables to achieve a temporary bonding between first handle 5 and second handle 15. This signifies that the mechanical bonding ensured by adhesive layer 16 between first handle 5 and second handle 15 may be broken by a treatment which does not damage the other elements of the structure, in particular first handle 5, second handle 15, and plate 20.

According to an embodiment, second handle 15 is detached from first handle 5 by removal or physico-chemical modification of adhesive layer 16. According to an embodiment, the removal or physico-chemical modification of adhesive layer 16 is achieved by a mechanical action, for example by the forming of a cut in adhesive layer 16 by means of a blade.

According to another embodiment, the removal or the physico-chemical modification of adhesive layer 16 is achieved by degradation of the material forming adhesive layer 16. According to an embodiment, the degradation of the material forming adhesive layer 16 is achieved by heating of adhesive layer 16. According to another embodiment, the degradation of the material forming adhesive layer 16 is achieved by chemical action on adhesive layer 16, carried out simultaneously with the heating of adhesive layer 16. According to another embodiment, the degradation of the material forming adhesive layer 16 is achieved by exposing adhesive layer 16 to a radiation, for example an ultraviolet, infrared, or visible light radiation, possibly from a laser source.

According to an embodiment, second handle 15 is removed by grinding and/or by CMP (Chemical-Mechanical Polishing) of second handle from surface 18. Adhesive layer 16 can then be removed by use of a solvent, by wet or dry etching, or by plasma incineration.

FIG. 10 is a cross-section view, partial and simplified, of the structure obtained after a mechanical breakage of first handle 5 from the bottom 9 of each groove 8. The mechanical breakage is achieved by mechanical devices which perform the fracture between grooves 8 and trenches 32 in the thin layer of material remaining of first handle 5 between the bottom 9 of grooves 8 and the bottom of trenches 32. First handle 5 is then separated into blocks 36, each block 36 being bonded to one of the electronic devices 22. The breakage areas 37 extend from the bottom 9 of each groove 8 to the surface 7 of the first handle 5 in the bottom 33 of trench 32 located in line with groove 8. Separate electronic systems 40 are thus obtained, each electronic system 40 comprising electronic device 22 and the block 36 to which it is bonded. According to an embodiment, the breakage step comprises the stretching of adhesive film 35 in the plane of adhesive film 35, the electronic devices 22 then being separated but still bonded to adhesive film 35, adhesive film 35 being in a stretched state, that is, tensile forces are exerted on the adhesive film in such a way that the surface area of the stretched adhesive film in top view corresponds to from 150% to 10,000% of the surface area of the same adhesive film on which no tensile forces are exerted. The stretched state of the adhesive film is maintained by mechanical means.

Electronic systems 40 may then be handled separately, for example by a pick-and-place system, not shown, and detached from adhesive film 35.

The method may comprise subsequent steps, in particular a step of removal of blocks 36 and of the adhesive layer 30 present under each electronic device 22. In the case where block 36 is kept for future use of the electronic device 22, and electronic device 22 comprises a light source, block 36 may advantageously be transparent to the light radiation emitted by electronic device 22.

The embodiment of the manufacturing method advantageously enables the laser treatment of first handle 5 to form grooves 8 not to damage the electronic components 25 on plate 20, since the laser treatment of first handle 5 is carried out before the bonding of plate 20 to first handle 5.

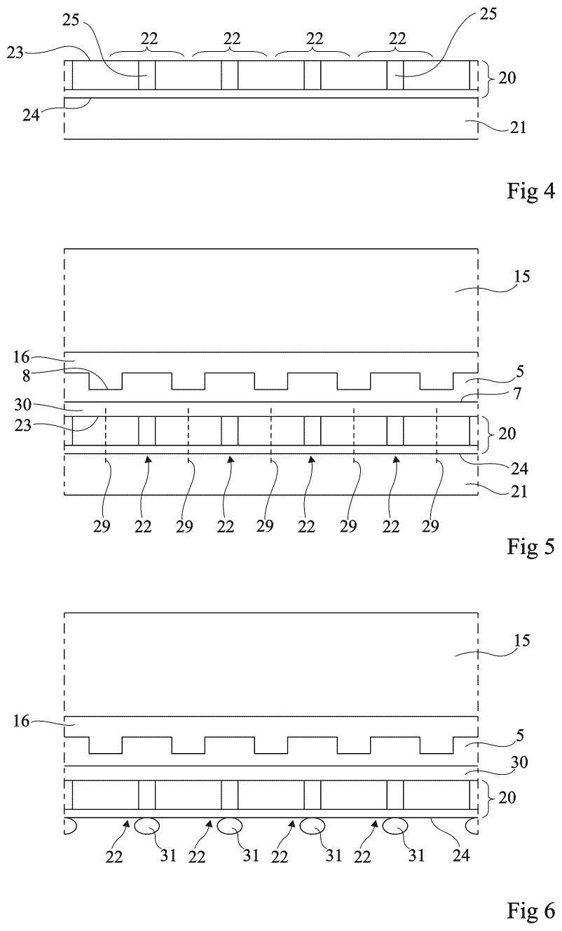

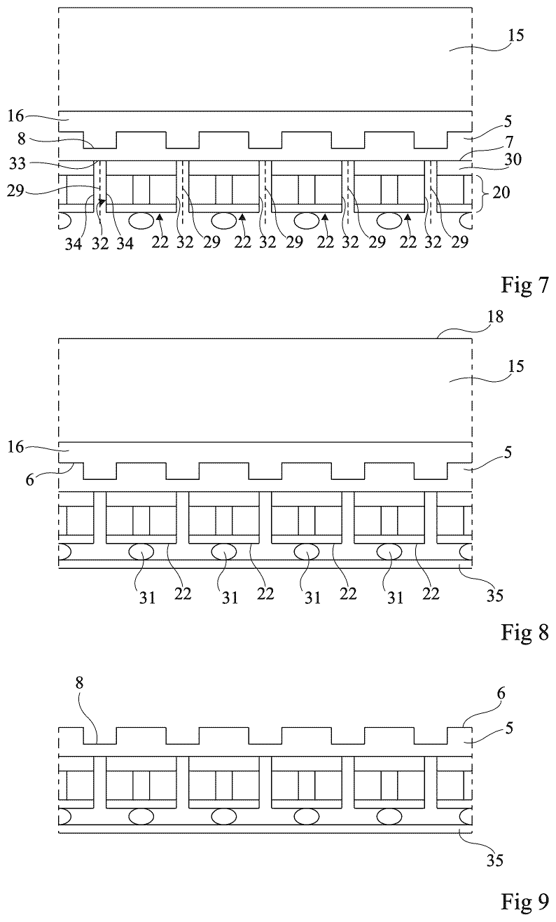

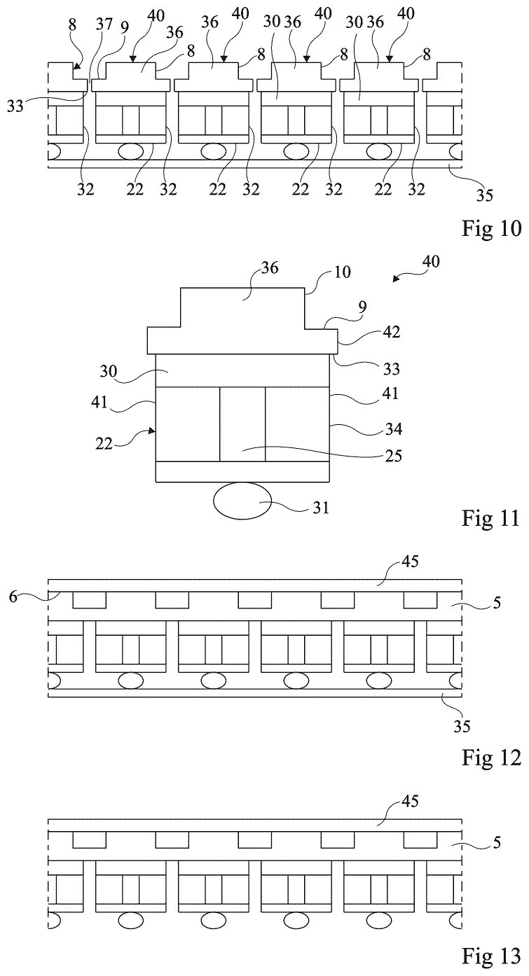

FIG. 11 is a cross-section view, partial and simplified, of the electronic system 40 of FIG. 10. Electronic system 40 comprises electronic device 22 and the block 36 to which it is bonded by a portion of adhesive layer 30. Electronic system 40 comprises flanks 41, each flank 41 comprising the side wall 34 of trench 32 used to delimit electronic device 22, a portion of the bottom 33 of this trench 32, a side wall 10 of the groove 8 that was located in line with trench 32, a portion of the bottom 9 of groove 8, and a wall 42 resulting from the breakage of first handle 5. According to an embodiment, wall 42 projects laterally from the wall 34 of electronic device 22. Further, according to an embodiment, wall 34 is not coplanar with wall 10.

FIG. 12, FIG. 13, and FIG. 14 are cross-section views, partial and simplified, of structures obtained at steps of another embodiment of a method of manufacturing an electronic device.

The initial steps are the same as those previously described in relation with FIGS. 1 to 9.

FIG. 12 is a cross-section view, partial and simplified, of the structure obtained after the bonding of an adhesive film 45, made of stretchable material, to the structure obtained in FIG. 9 on the side of first handle 5, more precisely on the side of the surface 6 of first handle 5.

FIG. 13 is cross-section view, partial and simplified, of the structure obtained after the removal of adhesive film 35.

FIG. 14 is a cross-section view, partial and simplified, of the structure obtained after a mechanical breakage of first handle 5 in line with each groove 8. Separate electronic devices 22 are thus obtained. According to an embodiment, the breakage step comprises the stretching of adhesive film 45 in the plane of adhesive film 45, the electronic devices 22 then being separated but still bonded to adhesive film 45 in a stretched state. As previously described, the electronic devices 40 can then be handled separately, for example by a pick-and-place system, not shown, and detached from adhesive film 45.

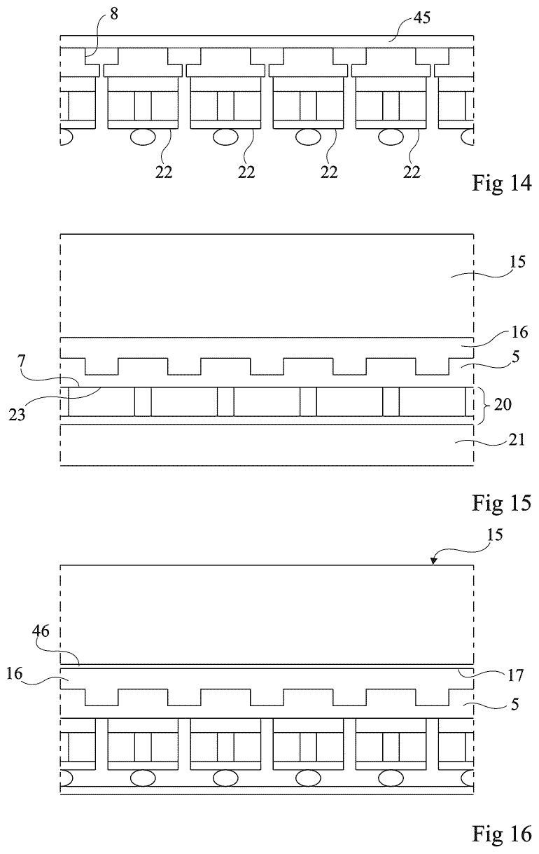

FIG. 15 is a cross-section view, partial and simplified, of the structure obtained at a step of another embodiment of a method of manufacturing an electronic device. The manufacturing method according to the present embodiment comprises the steps previously described in relation with FIGS. 1 to 10, with the difference that plate 20 is bonded to first handle 5 by a molecular bonding in which the surface 23 of plate 20 is brought into direct physical contact with the surface 7 of first handle 5 with no interposition of an additional bonding material.

FIG. 16 is a cross-section view, partial and simplified, of the structure obtained at a step of another embodiment of a method of manufacturing an electronic device. The manufacturing method according to the present embodiment comprises the steps previously described in relation with FIGS. 1 to 10 with the difference that second handle 15 comprises a sacrificial layer 46 on the side of surface 17, for example in contact with adhesive layer 16. At the step of removal of second handle 15, previously described in relation with FIG. 9, sacrificial layer 46 is degraded, for example by a laser treatment, to enable to remove second handle 15, and adhesive layer 16 is then removed, for example by chemical etching.

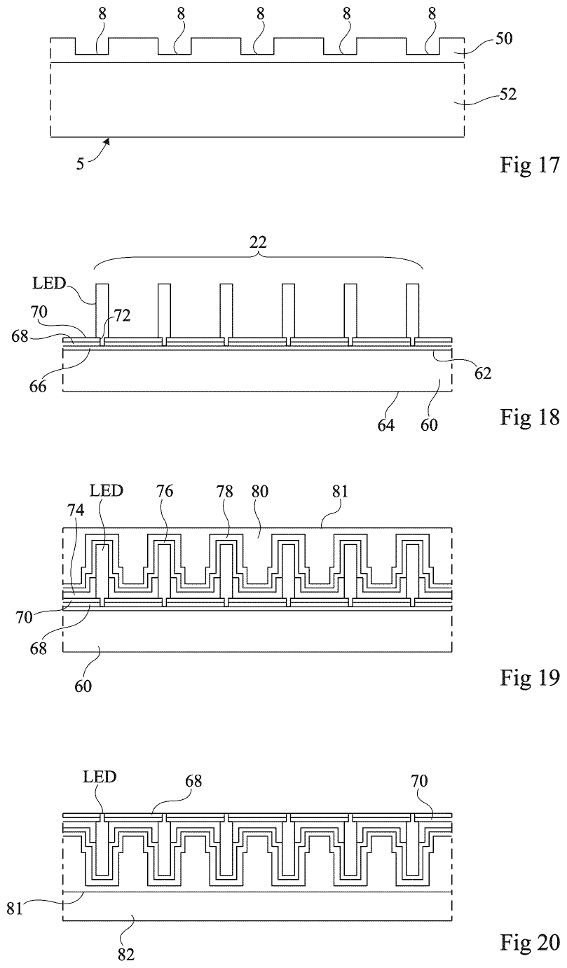

FIG. 17 is a cross-section view of first handle 5. According to an embodiment, first handle 5 has a multi-layer structure and comprises a layer 50 of a first material covering a substrate 52 made of a second material different from the first material. Grooves 8 are formed in layer 50. Substrate 52 may be transparent to the laser. According to an embodiment, the second material is a semiconductor material. The semiconductor material may be silicon, germanium, or a mixture of at least two of these compounds. Preferably, substrate 52 is made of silicon, more preferably of single-crystal silicon. As a variant, substrate 52 may be at least partly made of a non-semiconductor material, for example an electrically-insulating or electrically-conductive material. The thickness of layer 50 is in the range from 50 μm to 200 μm. Advantageously, the second material forming substrate 52 is selected to facilitate the thinning step previously described in relation with FIG. 3. In particular, the determination of the end of the thinning step is facilitated since it corresponds to the total removal of substrate 52. According to an embodiment, the first material is transparent to visible light. According to an embodiment, the first material comprises glass, quartz, and sapphire.

A more detailed embodiment will now be described in the case where electronic device 22 is an optoelectronic device and electronic components 25 comprise light-emitting diodes comprising three-dimensional semiconductor elements of nanometer- or micrometer-range dimensions, in particular microwires or nanowires or pyramid-shaped structures covered with the active layers. Indeed, for such optoelectronic devices 22, the carrying out of the separation of electronic devices 22 by using the forming of grooves while the plate containing electronic devices 22 is bonded to the first handle results in a significant deterioration of the light-emitting diodes next to the desired cutting lines.

The term “microwire” or “nanowire” designates a three-dimensional structure elongated along a preferred direction, at least two dimensions of which, called minor dimensions, are in the range from 5 nm to 5 μm, preferably from 100 nm to 2 μm, more preferably from 200 nm to 1.5 μm, the third dimension, called major dimension or height, being greater than or equal to 1 time, preferably greater than or equal to 3 times, and even more preferably greater than or equal to 5 times, the largest of the minor dimensions. In certain embodiments, the height of each microwire or nanowire may be greater than or equal to 500 nm, preferably in the range from 1 μm to 50 μm. In the rest of the disclosure, the term “wire” is used to mean “microwire or nanowire”.

The cross-section of the wires may have different shapes, for example, oval, circular or polygonal, in particular triangular, rectangular, square or hexagonal. It will be understood that the term “average diameter” used in relation with a cross-section of a wire designates a quantity associated with the area of the wire in this cross-section, corresponding, for example, to the diameter of the disk having the same area as the wire cross-section.

In the rest of the disclosure, the term pyramid designates a three-dimensional structure, a portion of which has a pyramidal or elongated conical shape. This pyramidal structure may be truncated, that is, the top of the cone is absent, leaving a plateau. The base of the pyramid is inscribed within a square having side dimensions from 100 nm to 10 μm, preferably between 0.2 μm and 2 μm. The polygon forming the base of the pyramid may be a hexagon. The height of the pyramid between the base of the pyramid and the apex or summit plateau varies from 100 nm to 20 μm, preferably between 200 nm and 2 μm.

In the rest of the disclosure, embodiments will be described in the case of an optoelectronic device with light-emitting diodes comprising microwires or nanowires. However, it should be clear that these embodiments may concern an optoelectronic device with light-emitting diodes comprising pyramids of micrometer- or nanometer-range dimensions.

The wires mostly comprise, preferably by more than 60% by mass, more preferably more than 80% by mass, at least one semiconductor material. The semiconductor material may be silicon, germanium, silicon carbide, a III-V compound, a II-VI compound, or a combination of at least two of these compounds.

Examples of group-III elements comprise gallium (Ga), indium (In), or aluminum (Al). Examples of III-N compounds are GaN, AlN, InN, InGaN, AlGaN, or AlInGaN. Other group-V elements may also be used, for example, phosphorus or arsenic. Generally, the elements in the III-V compound may be combined with different molar fractions. Examples of group-II elements comprise group-IIA elements, in particular beryllium (Be) and magnesium (Mg), and group-IIB elements, in particular zinc (Zn), cadmium (Cd), and mercury (Hg). Examples of group-VI elements comprise group-VIA elements, in particular oxygen (O) and tellurium (Te). Examples of II-VI compounds are ZnO, ZnMgO, CdZnO, CdZnMgO, CdHgTe, CdTe, or HgTe. Generally, the elements in the II-VI compound may be combined with different molar fractions. The semiconductor material of the wires may comprise a dopant, for example silicon ensuring an N-type doping of a III-N compound, or magnesium ensuring a P-type doping of a III-N compound.

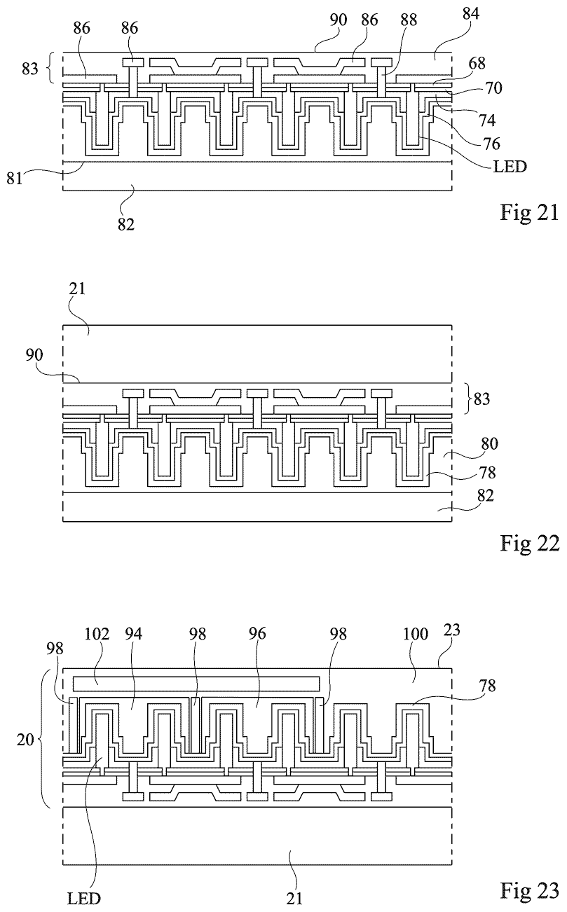

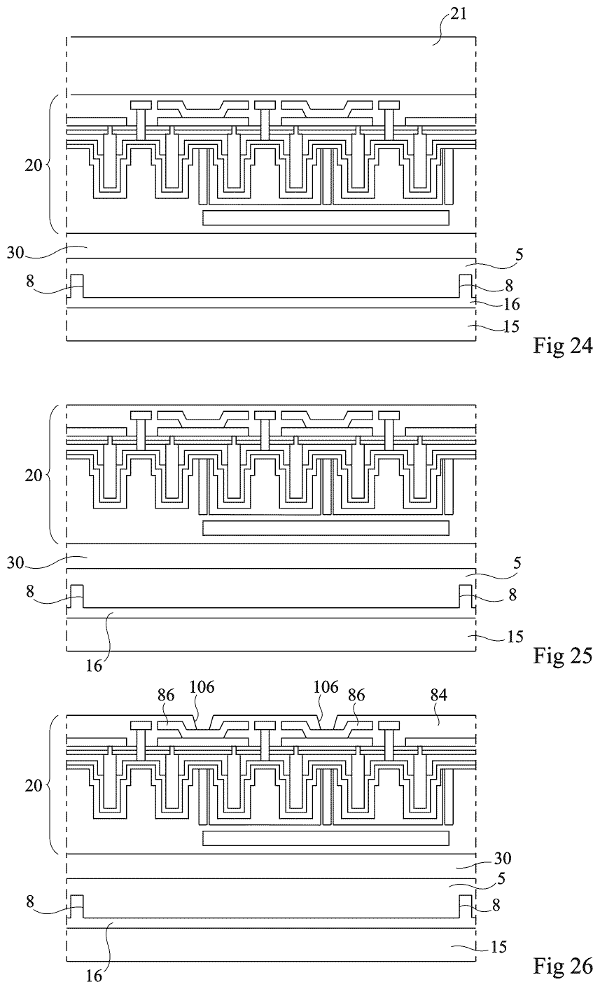

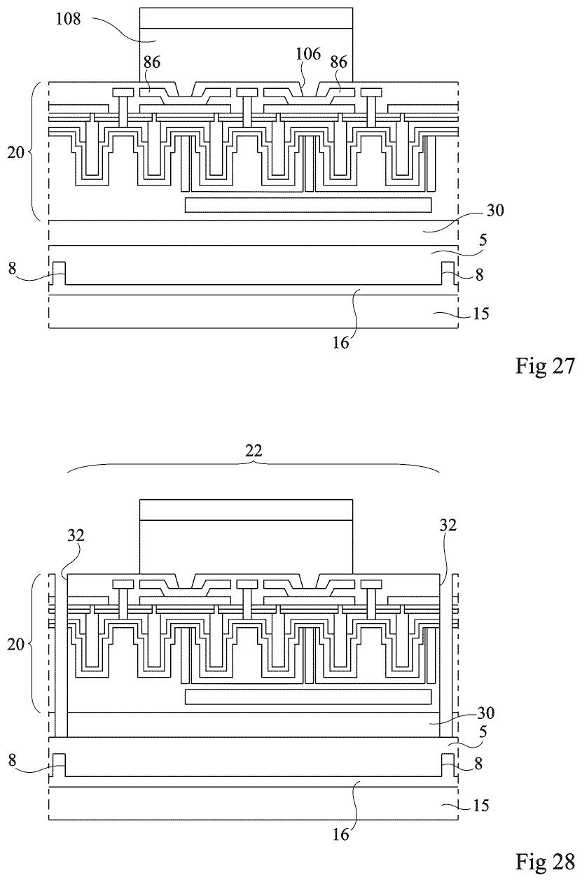

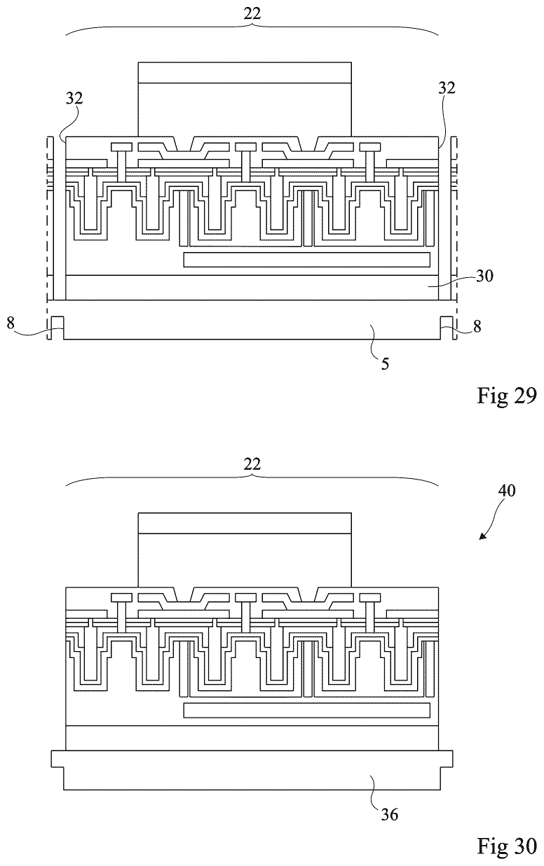

FIG. 18, FIG. 19, FIG. 20, FIG. 21, FIG. 22, FIG. 23, FIG. 24, FIG. 25, FIG. 26, FIG. 27, FIG. 28, FIG. 29, and FIG. 30 each are a cross-section view, partial and simplified, of the structure obtained at a step of an embodiment of a method of manufacturing optoelectronic device 22.

FIG. 18, FIG. 19, FIG. 20, FIG. 21, FIG. 22, and FIG. 23 illustrate the manufacturing of plate 20 on substrate 21, in the case where plate 20 comprises a plurality of copies of the optoelectronic device 22 comprising nanowires or microwires.

FIG. 18 is a cross-section view, partial and simplified, of the structure obtained after the following steps:
forming, on a substrate 60 comprising opposite surfaces 62 and 64, surface 62 preferably being planar at least at the location of the light-emitting diodes, of a seed layer 66 made of a material favoring wire growth and arranged on surface 62;
forming of a stack of two insulating layers 68 and 70 covering seed layer 66 and comprising openings 72 exposing portions of seed layer 66; and
growth, for each opening 72, of a light-emitting diode LED in contact with seed layer 66 through opening 72, six light-emitting diodes LED of a single optoelectronic device 22 being shown as an example in FIG. 18, light-emitting diodes LED being arranged in assemblies of light-emitting diodes LED.

FIG. 19 is a cross-section view, partial and simplified, of the structure obtained after the following steps:
forming of an insulating layer 74 extending over the side flanks of a lower portion of each light-emitting diode LED and extending over insulating layer 70 between the light-emitting diodes LED;
forming of a layer 76 forming an electrode covering each light-emitting diode LED and further extending over the insulating layer 74 between the light-emitting diodes LED;
forming of a protective dielectric layer 78 extending over layer 76; and
forming of a planarization layer 80 extending over layer 78 and having a planar free surface 81.

FIG. 20 is a cross-section view, partial and simplified, of the structure obtained after the following steps:
bonding of a handle 82 to surface 81; and
removal of substrate 60 and of seed layer 66 by any known means.

FIG. 21 is a cross-section view, partial and simplified, of the structure obtained after the forming, on insulating layer 68, of an interconnection structure 83 comprising a stack 84 of insulating layers and conductive tracks 86 of different metallization levels, conductive tracks 86 of two metallization levels being shown as an example in FIG. 21, and conductive vias 88 extending through the stack 84 of insulating layers, of insulating layer 68, and of insulating layer 74, and connecting electrode layer 76 to conductive tracks 86, interconnection structure 83 having a preferably planar free surface 90.

FIG. 22 is a cross-section view, partial and simplified, of the structure obtained after a step of bonding of substrate 21 to surface 90, for example by molecular bonding.

FIG. 23 is a cross-section view, partial and simplified, of the structure obtained by the following steps:
removal of handle 82 by any known means;
etching of insulating layer 80 at the location of certain assemblies of light-emitting diodes LED to expose these assemblies of light-emitting diodes LED, and between the assemblies of light-emitting diodes LED, insulating layer 80 being kept for the other assemblies of light-emitting diodes LED;
forming of photoluminescent blocks 94, 96 covering the exposed assemblies of light-emitting diodes LED, two photoluminescent blocks 94, 96 being shown as an example in FIG. 23;
forming of reflective walls 98 between blocks 94, 96;
forming of an encapsulation layer 100 covering each block 94, 96, and the protective dielectric layer 78 between blocks 94, 96, encapsulation layer 100 comprising the non-etched portions of insulating layer 80; and
forming, in encapsulation layer 100, of at least one color filter 102, for example a single yellow filter, covering at least some of photoluminescent blocks 94, 96, a single filter 102 covering both photoluminescent blocks 94, 96 being shown as an example in FIG. 23.

The structure resting on substrate 21 forms the plate 20 described hereabove, and the free surface 23 of encapsulation layer 100 corresponds to the above-described surface 23.

FIG. 24 is a cross-section view, partial and simplified, illustrating the step described hereabove in relation with FIG. 5, comprising the bonding by gluing of the surface 23 of plate 20 to first handle 5 by adhesive layer 30. In FIG. 24, first handle 5 is here shown with two grooves 8.

FIG. 25 is a cross-section view, partial and simplified, illustrating the step described hereabove in relation with FIG. 6, comprising the removal of substrate 21.

FIG. 26 is a cross-section view, partial and simplified, of the structure obtained after a step of forming of openings 106 in the stack 84 of insulating layers to expose conductive tracks 86.

FIG. 27 is a cross-section view, partial and simplified, of the structure obtained after a step of forming of conductive pads 108 in contact with the conductive tracks 86 exposed through openings 106, a single conductive pad 108 being shown as an example in FIG. 27. Each conductive pad 108 may have a monolayer or multilayer structure.

FIG. 28 is a cross-section view, partial and simplified, illustrating the step described hereabove in relation with FIG. 7, comprising the etching of trenches 32 in plate 20 at the location of the desired lines for separating electronic devices 22.

FIG. 29 is a cross-section view, partial and simplified, illustrating the step described hereabove in relation with FIG. 9, comprising the removal of second handle 15 and of adhesive layer 16.

FIG. 30 is a cross-section view, partial and simplified, illustrating the step described hereabove in relation with FIG. 10, comprising the breaking of first handle 5 at the location of grooves 8 to separate optoelectronic devices 22.

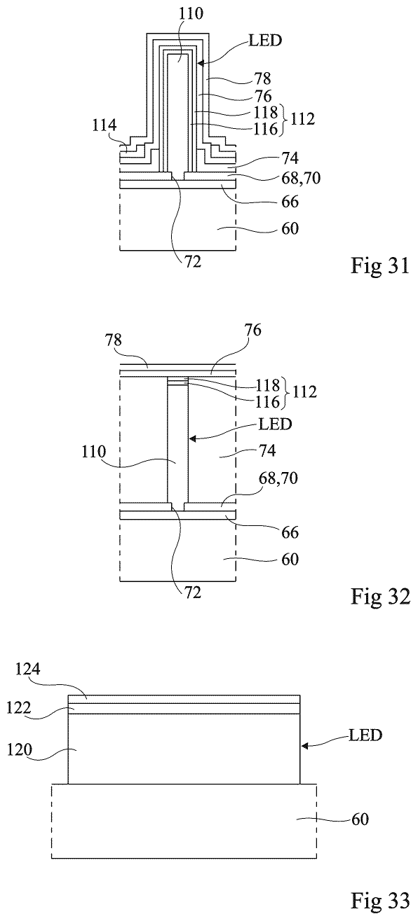

FIG. 31 shows an embodiment of light-emitting diodes LED. According to an embodiment, each light-emitting diode LED comprises a wire 110 in contact with seed layer 66 through one of openings 72, and a shell 112 comprising a stack of semiconductor layers covering the side walls and the top of wire 110. Such a configuration is said to be radial. The assembly formed by each wire 110 and the associated shell 112 forms light-emitting diode LED. In FIG. 31, there has further been shown a reflective layer 114, for example metallic, covering electrode layer 76 between wires 110 and in direct physical contact with electrode layer 76.

Shell 112 may comprise a stack of a plurality of layers, comprising in particular an active layer 116 and a bonding layer 118. Active layer 116 is the layer from which most, preferably all, of the radiation supplied by light-emitting diode LED is emitted. According to an example, active layer 116 may comprise confinement means, such as a single quantum well or multiple quantum wells. Bonding layer 118 may comprise a stack of semiconductor layers of the same III-V material as wire 110, but of the conductivity type opposite to that of wire 110.

FIG. 32 shows an embodiment of light-emitting diodes LED. The light-emitting diode LED shown in FIG. 32 comprises all the elements of the light-emitting diode LED shown in FIG. 31, with the difference that shell 112 is only present at the top of wire 110. Such a configuration is said to be axial.

The forming of the light-emitting diodes LED, that is, the growth of wires 110 in openings 72, and the forming of the shells 112 covering wires 110 may, for example, be achieved by metal-organic chemical vapor deposition (MOCVD) or any other adapted process.

Seed layer 66 is made of a material favoring wire growth. As an example, the material forming seed layer 66 may be a nitride, a carbide, or a boride of a transition metal from column IV, V, or VI of the periodic table of elements, or a combination of these compounds.

According to another embodiment, seed layer 66 may not be present. According to another embodiment, seed layer 66 may be replaced by seed pads, for example formed at the bottom of openings 72.

FIG. 33 shows an embodiment of light-emitting diodes LED. The light-emitting diode LED shown in FIG. 33 has a two-dimensional structure in that it is manufactured by the forming a stack of substantially flat semiconductor layers on substrate 60, followed by the delimiting of the light-emitting diode, for example by etching of trenches in the stack of semiconductor layers. The light-emitting diode shown in FIG. 33 comprises a doped semiconductor layer 120 of a first conductivity type, covered by an active layer 122, itself covered by a doped semiconductor layer 124 of a second conductivity type.

Substrate 60 may correspond to a monoblock structure or correspond to a layer covering a support made of another material. Substrate 60 is preferably a semiconductor substrate, for example, a substrate made of silicon, germanium, silicon carbide, III-V compound, such as GaN or GaAs, or a ZnO substrate. Preferably, substrate 60 is a single-crystal silicon substrate. Substrate 60 may correspond to a multilayer structure of silicon-on-insulator type, also known as SOI.

Each insulating layer 68, 70, 74, 78, 80, and encapsulation layer 100 may be made of a dielectric material, for example of silicon oxide (SiO₂), of silicon nitride (SiₓN_{y}, in particular with x and y approximately equal to 1, for example SiN, or with x approximately equal to 3 and y approximately equal to 4, for example Si₃N₄), of silicon oxynitride (in particular of general formula SiOₓN_{y}), of aluminum oxide (Al₂O₃), of hafnium oxide (HfO₂), of titanium dioxide (TiO₂), or of diamond. Each insulating layer 68, 70, 74, 78, 80 may have a monolayer structure or correspond to a stack of two or more than two layers.

Electrode layer 76 is adapted to letting through the electromagnetic radiation emitted by the light-emitting diodes. The material forming electrode layer 76 may be a transparent and conductive material such as indium tin oxide (ITO), or aluminum- or gallium-zinc oxide. The thickness of electrode layer 76 may be in the range from 0.01 μm to 1 μm.

According to an embodiment, each photoluminescent block 94, 96 is located opposite one of the light-emitting diodes LED or an assembly of light-emitting diodes. Each photoluminescent block 94, 96 comprises luminophores adapted, when they are excited by the light emitted by associated light-emitting diode LED, to emitting light at a wavelength different from the wavelength of the light emitted by the associated light-emitting diode LED.

Various embodiments and variants have been described. Those skilled in the art will understand that certain features of these various embodiments and variants could be combined, and other variants will become apparent to those skilled in the art.

Finally, the practical implementation of the described embodiments and variants is within the abilities of those skilled in the art, based on the functional indications given hereabove.

1. Method of manufacturing an electronic device, comprising the following steps:
forming, in a first handle having opposite first and second surfaces, of grooves in the first surface;
bonding of the first handle to a second handle on the side of the first surface;
thinning of the first handle on the side of the second surface;
manufacturing of a plate comprising a plurality of copies of the electronic device;
bonding of the plate to the second surface of the first handle;
forming of trenches in the plate in line with the grooves;
removal of the second handle; and
breakage of the first handle at the bottom of the grooves to separate the electronic devices.

2. Method according to claim 1, wherein the grooves are formed by laser etching.

3. Method according to claim 1, wherein the bonding of the first handle to the second handle is performed by gluing with a first layer of adhesive.

4. Method according to claim 3, wherein the step of removal of the second handle further comprises a step of removal, total or partial, of the first adhesive layer.

5. Method according to claim 1, wherein the bonding of the plate to the first handle is performed by gluing with a second layer of adhesive.

6. Method according to claim 5, wherein the trenches further extend in the second adhesive layer.

7. Method according to claim 1, wherein the bonding of the plate to the first handle is performed by molecular bonding.

8. Method according to claim 1, wherein the trenches are formed by etching of the plate by dry etching or wet etching.

9. Method according to claim 1, wherein the step of bonding of the plate to the first handle comprises a step of positioning of first marks of the first handle relative to second marks of the plate, so that each electronic device to be separated is positioned between four grooves from among the grooves.

10. Method according to claim 1, wherein the first handle is at least partly made of glass, of quartz, or of sapphire.

11. Method according to claim 1, wherein, when projected in a plane parallel to the second surface, one of the grooves is located between each pair of adjacent electronic devices.

12. Structure comprising:
a first handle having first and second surfaces and grooves in the first surface;
a plate comprising a plurality of copies of an electronic device bonded to the first handle on the side of the second surface; and
a second handle bonded to the first handle on the side of the first surface.

13. Structure according to claim 12, further comprising a first layer of adhesive between the first handle and the second handle.

14. Structure according to claim 12, further comprising a second layer of adhesive between the plate and the first handle.

15. Structure according to claim 12, wherein, when projected in a plane parallel to the second surface, one of the grooves is located between each pair of adjacent electronic devices.

16. Structure according to claim 12, wherein the grooves delimit pads in the first handle, each pad facing a single one of the electronic devices.

17. Electronic system comprising an electronic device having a first side wall and a block having first and second opposite surfaces and a second side wall, the electronic device being bonded to the second surface, the electronic system further comprising flanks containing the first side wall, the second side wall, and a portion coupling the first side wall to the second side wall projecting from the first side wall and from the second side wall.

18. Electronic system according to claim 17, wherein the electronic device comprises light-emitting diodes.

19. Electronic system according to claim 18, wherein each light-emitting diode comprises a three-dimensional semiconductor element of nanometer- or micrometer-range dimensions, corresponding to a microwire, a nanowire, or a pyramid-shaped structure of nanometer- or micrometer-range dimensions, and an active layer covering the three-dimensional semiconductor element.
